(19) United States
(12) Patent Application Publication
(10) Pub. No.: US 2006/0109898 A1
(43) Pub. Date: May 25, 2006

(54) Powerline communication PHY with a digital direct drive output stage

(75) Inventors: Oleg Logvinov, East Brunswick, NJ (US); Brion Ebert, Easton, PA (US)

Correspondence Address: Jim Reeber, 948 US Highway 22, North Plainfield, NJ, 07060, US

(73) Assignee: Arkados, Inc

(21) Appl. No.: 11/281,072

(22) Filed: Nov. 17, 2005

Related U.S. Application Data
(60) Provisional application No. 60/628,846, filed on Nov. 17, 2004.

(51) Int. Cl. H03K 7/08; H04L 5/16; G05B 11/01

(52) U.S. Cl. 375/238; 375/220; 375/222; 340/310.12

(57) ABSTRACT

It is possible to implement a Power Line Communication (PLC) PHY utilizing a digital direct drive output stage that converts the digital output waveform into an analog signal on the power line through pulse width modulation at a very high frequency. Utilizing PWM circuitry instead of a DAC can reduce the silicon real estate size of the PHY, and the quantization noise of the output signal, as well as improve the input to output efficiency. The power dissipation of the device can also be reduced by the elimination of the linear amplification mode of the output driver stage.

### CROSS REFERENCE TO RELATED APPLICATION

This application claims the benefit of U.S. Provisional Application No. 60/628,846 filed Nov. 17, 2004, assigned to the assignee of this application and incorporated by reference herein.

### FIELD OF THE INVENTION

The preset invention relates to a power line communication (PLC) system for local area networks and wide area networks. This system has uses in two areas: (1) a common power line access network that provides electricity to homes, businesses, and other entities, and (2) a common local power line network in a home, business or other environment. Both of these networks can be used to support communication between electronic appliances coupled to these lines. The invention relates to this field of data communications over conventional electric power conveying media, utilizing broadband frequency division multiplexing methods. More particularly, this invention relates to the physical data signal output portion of a broadband data communication system device, where the digital data to be communicated is converted to an analog signal for transmission on the power line medium.

### BACKGROUND OF THE INVENTION

A common power transmission network can be viewed as having three (3) main segments. A distribution access network of medium voltage power lines, configured in a loop and several miles in length, connects a standard power substation to an area of homes and businesses. At various points on the loop, step down transformers provide a series of 110-240 V low voltage access lines, depending on the country, to a small number of homes and/or businesses. At the end of each one of these lines, a meter or meters is typically present for each electricity customer served by that line. On the other side of each meter is a typical in-home or in-building electricity distribution network, which is contained inside a home or business.

It is well known in the art that an electric power distribution network, which is composed of conventional electric wires and associated power transformer equipment, can operate to convey electricity along the electric wires having voltages from about 90 VAC to 20 KVAC and frequencies from about 40 Hz to 400 Hz. The physical communications protocol layer component of PLC transmitter and receiver devices that form a PLC system, therefore, must operate in relation to the ranges of voltages and frequencies associated with the electric power distribution network on which the PLC devices are installed to ensure that communication over the PLC network is maintained robust.

Currently, Orthogonal Frequency Division Multiplexing (OFDM) based communication methods are available and are used on various types of mediums, both wired and wireless, including power line communications networks. An OFDM based communications system normally contains a Physical Layer interface (“PHY”) and Media Access Control (“MAC”) functionality. In current PLC transmission and reception devices, the PHY interface is designed to operate according to the characteristics of the electric power distribution network for which installation of the PLC device is planned. The PHY functionality of these devices is typically a large portion of the overall design in terms of silicon size, due to the high frequency and high precision requirements of the communication protocol. This functionality also typically has the characteristics of high power dissipation and less than ideal efficiencies. Therefore, there exists a need to construct a PLC device with a PHY functionality that is smaller in silicon size, and dissipates less power, while also improving its power efficiency.

### SUMMARY OF THE INVENTION

Broadband power line data communication systems typically utilize a high frequency, high precision, digital to analog converter (DAC), along with a high power line driver on the output stage of the communication system. These devices are typically large in silicon size and high in power consumption. It is possible to utilize a pulse width modulator (PWM) at very high frequency with a direct digital output stage to accomplish this same function. The use of this method would reduce the size of the design in silicon area, reduce the quantization noise in the output stage, and would also reduce the overall power consumption of the design.

In U.S. Pat. No. 5,930,128, Dent details how waveform synthesizers, along with a plurality of bilateral amplifiers, can be constructed to a digital to analog converter (DAC). The waveform synthesizers represent an input waveform as a sequence of numerical codes in a number base, which corresponds to the digital input data. The bilateral amplifiers would be associated with each respective one of the digits. They will then generate an output voltage level that is proportional to the value of the associated digit. The output voltage levels of the plurality of bilateral amplifiers are serially coupled to the load, with a weighting that is based upon the place significance of the associated digit. Waveform synthesizers that are so constructed are capable of theoretical efficiencies of 100% for any signal waveform. These waveform synthesizers may be used efficiently to amplify to a transmit power level or radio signal that varies in amplitude as well as phase.

In U.S. Pat. No. 6,529,071, Casier, et al. detail a direct drive amplifier and output driver for xDSL applications. The use of a switch mode driver with active back termination can be used to significantly reduce the power consumption of the amplifier. The use of a switch mode driver, arranged in parallel with a linear amplifier, can be configured to improve the operating efficiency of the amplifier as well.

Considering the above concepts, it is therefore possible to utilize a pulse width modulator (PWM) at very high frequency with a direct digital output stage to accomplish the DAC and amplifier functions of a PLC PHY. It can be seen that the use of this method would reduce the size of the design in silicon area, reduce the quantization noise in the output stage, and would also reduce the overall power consumption of the design, as well as improve the input to output efficiency.

What is claimed is:

1. A Powerline Communication PHY with a digital direct drive output stage that converts the digital output waveform into an analog signal on the powerline through pulse width modulation at a very high frequency.

2. The system in claim 1 where a size of the silicon real estate is reduced through the elimination of the DAC block and replacement of it with a PWM type of driving circuitry.

3. The system in claim 1 where the quantization noise is reduced through the use of a very high frequency PWM type of converter instead of a DAC.

4. The system in claim 1 where the output efficiency is improved through the use of a very high frequency PWM type of converter instead of a DAC.

5. The system in claim 1 where power dissipation is reduced by the elimination of the linear amplification mode of operation in the output driver stage.

6. The system in claim 1 where a tracking feedback is used to adjust output parameters to overcome non-linearity and artifacts of the transmission system and coupling components.
